(19) United States
(12) Patent Application Publication
(10) Pub. No.: US 2025/0275136 A1
(43) Pub. Date: Aug. 28, 2025

(54) MEMORY DEVICE AND MANUFACTURING METHOD OF THE MEMORY DEVICE

(71) Applicant: SK hynix Inc., Icheon-si Gyeonggi-do (KR)

(72) Inventors: In Su PARK, Icheon-si Gyeonggi-do (KR); Won Geun CHOI, Icheon-si Gyeonggi-do (KR)

(73) Assignee: SK hynix Inc., Icheon-si Gyeonggi-do (KR)

(21) Appl. No.: 18/769,617

(22) Filed: Jul. 11, 2024

(30) Foreign Application Priority Data
Feb. 27, 2024 (KR) 10-2024-0027998

(51) Int. Cl. H10B 43/27

(52) U.S. Cl. CPC H10B 43/27

(57) ABSTRACT

A memory device according to an embodiment of the present disclosure includes a stack structure including a cell region and a contact region, a cell plug located in the cell region and including a channel layer, a support pillar located in the contact region and including a dummy channel layer, and a contact opening contacting the support pillar wherein a thickness of the dummy channel layer is greater than a thickness of the channel layer.

### CROSS-REFERENCE TO RELATED APPLICATION

The present application claims priority under 35 U.S.C. § 119(a) to Korean patent application number 10-2024-0027998 filed on Feb. 27, 2024, in the Korean Intellectual Property Office, the entire contents of which application is incorporated herein by reference.

### BACKGROUND

### 1. Technical Field

Various embodiments of the present disclosure generally relate to a memory device and a manufacturing method of the memory device, and more particularly, to a memory device including a three-dimensional memory block and a method of manufacturing the memory device.

### 2. Related Art

A memory device may include a non-volatile memory device in which stored data is retained even when power supply is interrupted. The non-volatile memory device may be classified as a two-dimensional structure or a three-dimensional structure according to a structure in which memory cells are arranged. Memory cells of a non-volatile memory device having a two-dimensional structure may be arranged in a single layer on a substrate, and memory cells of a non-volatile memory device having a three-dimensional structure may be stacked in a vertical direction on the substrate. Since a degree of integration of the non-volatile memory device having the three-dimensional structure is higher than that of integration of the non-volatile memory device having the two-dimensional structure, electronic devices using non-volatile memory devices having a three-dimensional structure have recently been increasing in popularity.

### SUMMARY

According to an embodiment, a memory device may include a stack structure including a cell region and a contact region, a cell plug located in the cell region and including a channel layer, a support pillar located in the contact region and including a dummy channel layer, and a contact opening contacting the support pillar, wherein a thickness of the dummy channel layer is greater than a thickness of the channel layer.

According to an embodiment, a method of manufacturing a memory device may include forming a preliminary stack structure including a cell region and a contact region, forming a first opening penetrating the cell region and a second opening penetrating the contact region, forming a channel layer having a first thickness in the first opening, forming a dummy channel layer having a second thickness in the second opening, wherein the second thickness is greater than the first thickness, and forming a contact opening contacting the dummy channel layer.

### BRIEF DESCRIPTION OF THE DRAWINGS

FIG. 1 is a diagram illustrating a memory device according to an embodiment of the present disclosure;

FIG. 2 is a diagram schematically illustrating a memory device according to an embodiment of the present disclosure;

FIGS. 3A, 3B, and 3C are diagrams illustrating a memory device including support pillars according to an embodiment of the present disclosure;

FIGS. 4A, 4B, 4C, 4D, 4E, and 4F are diagrams illustrating a method of manufacturing a memory device including support pillars according to an embodiment of the present disclosure;

FIG. 5 is a diagram illustrating a memory device including support pillars according to other embodiments of the present disclosure;

FIG. 6 is a diagram illustrating a memory card system to which a memory device according to an embodiment of the present disclosure is applied; and

FIG. 7 is a diagram illustrating a solid state drive (SSD) system to which a memory device according to an embodiment of the present disclosure is applied.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein.

Hereinafter, embodiments of the present disclosure will be described in detail with reference to the accompanying drawings in order for those skilled in the art to be able to implement the technical spirit of the present disclosure.

It will be understood that when an element or layer etc., is referred to as being “on,” “connected to” or “coupled to” another element or layer etc., it can be directly on, connected or coupled to the other element or layer etc., or intervening elements or layers etc., may be present. In contrast, when an element or layer etc., is referred to as being “directly on,” “directly connected to” or “directly coupled to” another element or layer etc., there are no intervening elements or layers etc., present. It will be understood that although the terms first, second, third etc. may be used herein to describe various elements, these elements should not be limited by these terms. These terms are only used to distinguish one element from another element, but not used to define only the element itself or to mean a particular sequence.

Various embodiments relate to a memory device capable of enhancing the structural stability of a stack structure and a method of manufacturing the memory device.

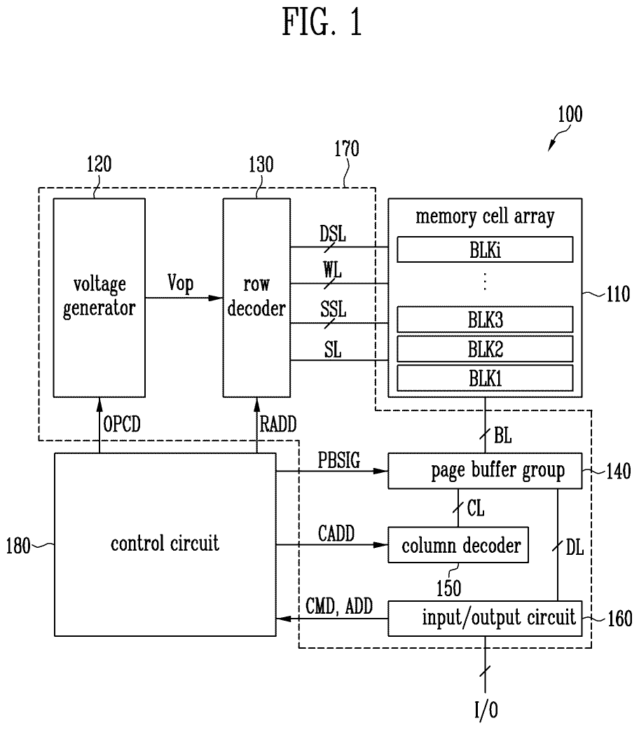

FIG. 1 is a diagram illustrating a memory device 100 according to an embodiment of the present disclosure.

Referring to FIG. 1, the memory device 100 may include a memory cell array 110, a peripheral circuit 170, and a control circuit 180.

The memory cell array 110 may include first to ith memory blocks BLK1 to BLKi, where i is a positive integer. Each of the first to ith memory blocks BLK1 to BLKi may include memory cells capable of storing data. Drain select lines DSL, word lines WL, source select lines SSL, and a source line SL may be coupled to each of the first to ith memory blocks BLK1 to BLKi, and bit lines BL may be commonly coupled to the first to ith memory blocks BLK1 to BLKi.

The first to ith memory blocks BLK1 to BLKi may have a three-dimensional structure. Memory blocks having a three-dimensional structure may include memory cells stacked in a vertical direction on a substrate.

Memory cells may store one-bit or two-or-more-bit data according to a program method. For example, a method in which one-bit data is stored in one memory cell is referred to as a single-level cell (SLC) method, and a method in which two-bit data is stored in one memory cell is referred to as a multi-level cell (MLC) method. A method in which three-bit data is stored in one memory cell is referred to as a triple-level cell (TLC) method, and a method in which four-bit data is stored in one memory cell is referred to as a quad-level cell (QLC) method. In addition, five-or-more-bit data may be stored in one memory cell.

The peripheral circuit 170 may be configured to perform a program operation that stores data in the memory cell array 110, a read operation that outputs data stored in the memory cell array 110, and an erase operation that erases data stored in the memory cell array 110. For example, the peripheral circuit 170 may include a voltage generator 120, a row decoder 130, a page buffer group 140, a column decoder 150, and an input/output circuit 160.

The voltage generator 120 may generate various operating voltages Vop used for a program operation, a read operation, or an erase operation in response to an operation code OPCD. For example, the voltage generator 120 may be configured to generate program voltages, turn-on voltages, turn-off voltages, negative voltages, pre-charge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a selected memory block by the row decoder 130.

The program voltages may be applied to a selected word line among the word lines WL during a program operation, and may be used to increase threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or the source select transistors. For example, the turn-off voltages may be set to 0 V. The pre-charge voltages may be higher than 0 V, and may be applied to the bit lines BL during a read operation. The verify voltages may be used during a verify operation to determine whether threshold voltages of selected memory cells have been increased to a target level. The verify voltages may be set to various levels according to the target level, and may be applied to the selected word line.

The read voltages may be applied to the selected word line during a read operation of the selected memory cells. For example, the read voltages may be set to various levels according to a program method of the selected memory cells. The pass voltages may be applied to unselected word lines among the word lines WL during a program or read operation, and may be used to turn on memory cells coupled to the unselected word lines. The erase voltages may be used during an erase operation to erase the memory cells included in the selected memory block, and may be applied to the source line SL.

The row decoder 130 may be configured to transfer the operating voltages Vop to the drain select lines DSL, the word lines WL, the source select lines SSL, and the source line SL that are coupled to the selected memory block according to a row address RADD. For example, the row decoder 130 may be coupled to the voltage generator 120 through global lines, and may be coupled to the first to ith memory blocks BLK1 to BLKi through the drain select lines DSL, the word lines WL, the source select lines SSL, and the source line SL.

The page buffer group 140 may include page buffers (not shown) respectively coupled to the first to ith memory blocks BLK1 to BLKi. The page buffers (not shown) may be coupled to the first to ith memory blocks BLK1 to BLKi through the bit lines BL, respectively. During a read operation, the page buffers (not shown) may sense a current or a voltage of the bit lines BL that varies according to the threshold voltages of the selected memory cells and may temporarily store sensed data in response to page buffer control signals PBSIG.

The column decoder 150 may be configured to transfer data between the page buffer group 140 and the input/output circuit 160 in response to a column address CADD. For example, the column decoder 150 may be coupled to the page buffer group 140 through column lines CL and may transfer enable signals through the column lines CL. The page buffers (not shown) included in the page buffer group 140 may receive or output data through data lines DL in response to the enable signals.

The input/output circuit 160 may be configured to receive or output a command CMD, an address ADD, or data through input/output lines I/O. For example, the input/output circuit 160 may transfer the command CMD and the address ADD, which are received from an external controller, to the control circuit 180 through the input/output lines I/O, and may transfer data received from the external controller to the page buffer group 140 through the input/output lines I/O. In addition, the input/output circuit 160 may output data transferred from the page buffer group 140 to the external controller through the input/output lines I/O.

The control circuit 180 may output at least one of the operation code OPCD, the row address RADD, the page buffer control signals PBSIG, and the column address CADD in response to the command CMD and the address ADD. For example, when the command CMD input to the control circuit 180 corresponds to a program operation, the control circuit 180 may control the peripheral circuit 170 to perform the program operation of a memory block selected by the address ADD. When the command CMD input to the control circuit 180 corresponds to a read operation, the control circuit 180 may control the peripheral circuit 170 to perform the read operation of the memory block selected by the address ADD and output read data. When the command CMD input to the control circuit 180 corresponds to an erase operation, the control circuit 180 may control the peripheral circuit 170 to perform the erase operation of the selected memory block.

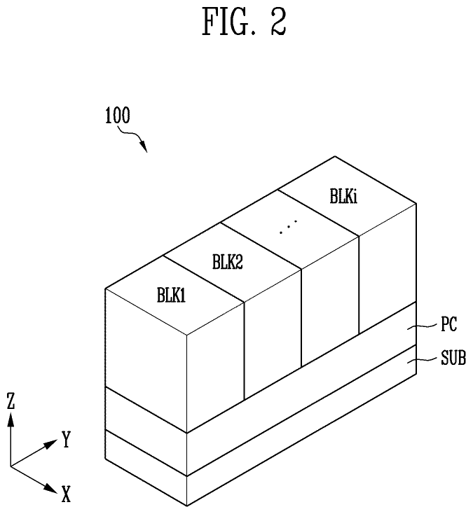

FIG. 2 is a diagram schematically illustrating the memory device 100 according to an embodiment of the present disclosure.

Referring to FIG. 2, the memory device 100 may include a peripheral circuit structure PC and the first to ith memory blocks BLK1 to BLKi disposed on a substrate SUB. The first to ith memory blocks BLK1 to BLKi may overlap the peripheral circuit structure PC.

The substrate SUB may be a single crystal semiconductor layer. For example, but not limited to, the substrate SUB may be a bulk silicon substrate, a silicon-on-insulator substrate, a germanium substrate, a germanium-on-insulator substrate, a silicon-germanium substrate, or an epitaxial thin film formed through a selective epitaxial growth method.

The peripheral circuit structure PC may include the row decoder 130, the column decoder 150, the page buffer group 140, and the control circuit 180 which constitute circuitry for controlling the operations of the first to ith memory blocks BLK1 to BLKi. For example, but not limited to, the peripheral circuit structure PC may include an NMOS transistor, a PMOS transistor, a resistor, and a capacitor that are electrically coupled to the first to ith memory blocks BLK1 to BLKi. The peripheral circuit structure PC may be disposed between the substrate SUB and the first to ith memory blocks BLK1 to BLKi.

Each of the first to ith memory blocks BLK1 to BLKi may include a source structure, bit lines, cell strings that are electrically coupled between the source structure and the bit lines, word lines that are electrically coupled to the cell strings, and select lines that are electrically coupled to the cell strings. Each of the cell strings may include memory cells and select transistors that are coupled in series by a cell plug. Each of the select lines may serve as a gate electrode of a corresponding select transistor, and each of the word lines may serve as a gate electrode of a corresponding memory cell.

In another embodiment, the substrate SUB, the peripheral circuit structure PC, and the first to ith memory blocks BLK1 to BLKi may be stacked in a reverse order with respect to the order shown in FIG. 2. For example, the peripheral circuit structure PC may be disposed over the first to ith memory blocks BLK1 to BLKi.

In another embodiment, contrary to FIG. 2, the peripheral circuit structure PC may be disposed over some areas of the substrate SUB that do not overlap the first to ith memory blocks BLK1 to BLKi. For example, the peripheral circuit structure PC and the first to ith memory blocks BLK1 to BLKi may be respectively disposed in areas of the substrate SUB that do not overlap each other.

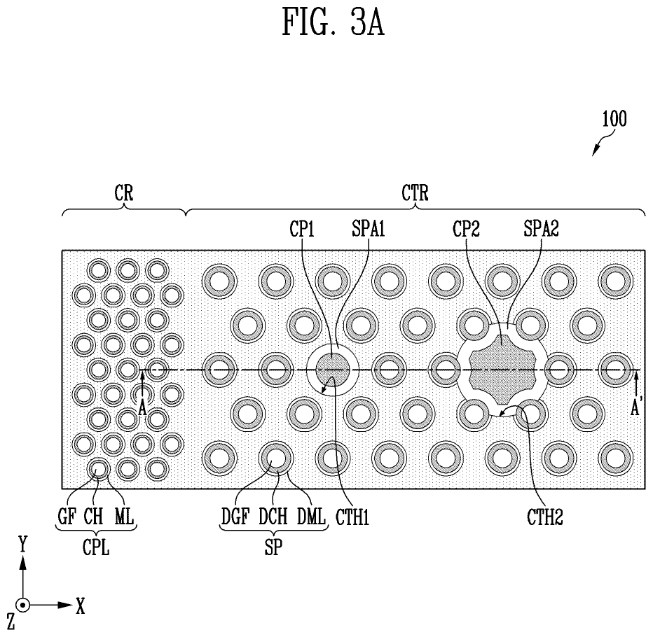

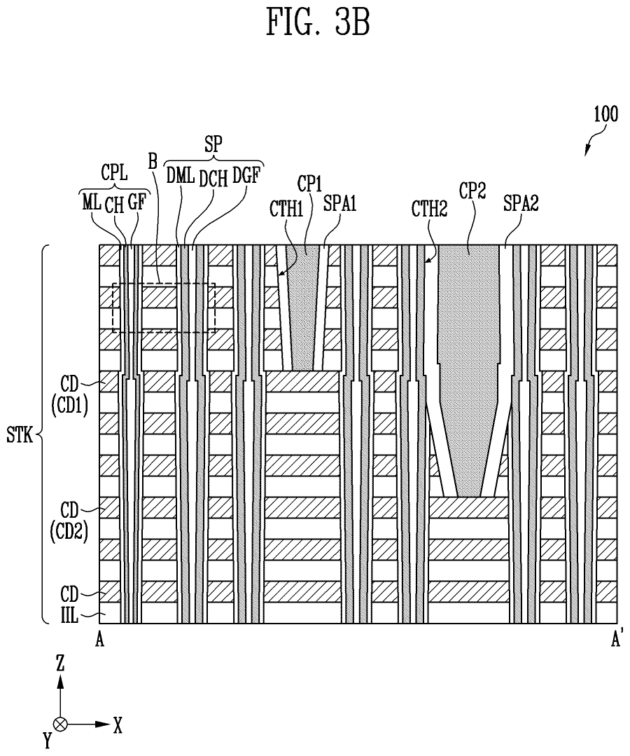

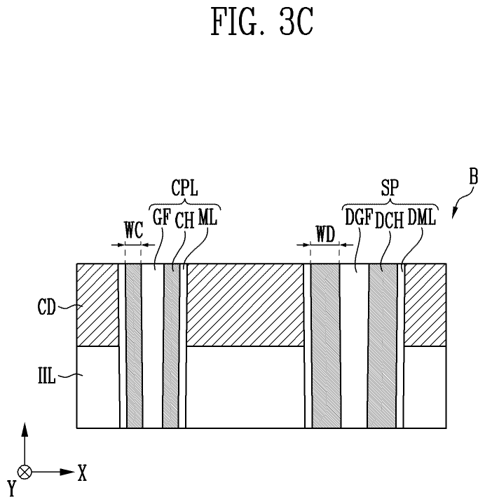

FIGS. 3A to 3C are diagrams illustrating a memory device including support pillars according to an embodiment of the present disclosure. FIG. 3A is a plan view illustrating a layout of a memory device according to an embodiment of the present disclosure. FIG. 3B shows a cross-section taken along line A-A′ of FIG. 3A. FIG. 3C is an enlarged view of B of 3B.

Referring to FIG. 3A, the memory device 100 may include a cell region CR and a contact region CTR. The contact region CTR may be located in an X direction of the cell region CR. The contact region CTR may extend in the X direction from the cell region CR. In some other embodiments, apart from those shown in FIG. 3A, the contact region CTR may extend in a Y direction or both in the X and Y directions from the cell region CR. In addition, the cell region CR and the contact region CTR may be disposed at various locations.

Cell plugs CPL may be located in the cell region CR. The cell plugs CPL may be disposed in the X and Y directions. The cell plugs CPL may be spaced apart from each other in the X and Y directions. Each of the cell plugs CPL may extend in a Z direction. Each of the cell plugs CPL may serve as a channel region of a cell string. Each of the cell plugs CPL may be electrically coupled to a bit line (e.g., the bit line BL in FIG. 1) and a source line (e.g., the source line SL in FIG. 1) through a line structure.

Each of the cell plugs CPL may include a memory layer ML, a channel layer CH, and a gap fill layer GF. The memory layer ML may have a cylindrical shape. The memory layer ML may surround the channel layer CH. Though not shown, the memory layer ML may include a blocking layer, a charge trap layer and a tunnel insulating layer. The channel layer CH may be formed along an inner wall of the memory layer ML. The gap fill layer GF may fill an inside of the channel layer CH. The gap fill layer GF may have a cylindrical shape surrounded by the channel layer CH.

The blocking layer and the tunnel insulating layer included in the memory layer ML may include an oxide layer (e.g., a silicon oxide layer), an oxynitride layer (e.g., a silicon oxynitride layer), or a combination thereof. The charge trap layer included in the memory layer ML may include a nitride layer or a variable resistance material. The channel layer CH may include an undoped silicon layer or a doped silicon layer. The gap fill layer GF may include an insulating layer (e.g., an oxide layer).

Support pillars SP may be located in the contact region CTR. The support pillars SP may be arranged in the X and Y directions. The support pillars SP may be spaced apart from each other in the X and Y directions. Each of the support pillars SP may extend in the Z direction. A planar area of the support pillar SP may be greater than a planar area of the cell plug CPL.

The support pillar SP may have a similar structure to the cell plug CPL. Each of the support pillars SP may include a dummy memory layer DML, a dummy channel layer DCH, and a dummy gap fill layer DGF. The dummy memory layer DML may have a cylindrical shape. The dummy memory layer DML may surround the dummy channel layer DCH. Though not shown, the dummy memory layer DML may include a dummy blocking layer, a dummy charge trap layer, and a dummy tunnel insulating layer. The dummy channel layer DCH may be formed along an inner wall of the dummy memory layer DML. The dummy gap fill layer DGF may fill an inside of the dummy channel layer DCH. The dummy gap fill layer DGF may have a cylindrical shape surrounded by the dummy channel layer DCH.

The dummy blocking layer, the dummy charge trap layer, and the dummy tunnel insulating layer included in the dummy memory layer DML may include the same material as the blocking layer, the charge trap layer, and the tunnel insulating layer included in the memory layer ML, respectively. The dummy channel layer DCH may include the same material as the channel layer CH. The dummy gap fill layer DGF may include the same material as the gap fill layer GF.

First and second contact plugs CP1 and CP2 may be located in the contact region CTR. A plurality of contact plugs may be disposed in the contact region CTR, and the first and second contact plugs CP1 and CP2 are described in FIG. 3A. Each of the first and second contact plugs CP1 and CP2 may extend in the Z direction. The first and second contact plugs CP1 and CP2 may include a conductive material.

The first and second contact plugs CP1 and CP2 may be disposed between the support pillars SP. The first and second contact plugs CP1 and CP2 may be disposed adjacent to the support pillars SP. For example, each of the first and second contact plugs CP1 and CP2 may be formed to be surrounded by six support pillars SP. The first and second contact plugs CP1 and CP2 may be spaced apart from the support pillars SP.

The first and second contact plugs CP1 and CP2 may be located in first and second contact openings CTH1 and CTH2, respectively. In this embodiment, the first and second contact openings CTH1 and CTH2 may be understood as contact holes. First and second spacers SPA1 and SPA2 surrounding side surfaces of the first and second contact plugs CP1 and CP2 may be disposed in the first and second contact openings CTH1 and CTH2, respectively. For example, the first contact plug CP1 and the first spacer SPA1 may be disposed in the first contact opening CTH1. In addition, the second contact plug CP2 and the second spacer SPA2 may be disposed in the second contact opening CTH2. The first and second spacers SPA1 and SPA2 may include an insulating layer (e.g., an oxide layer).

A planar area of each of the first and second contact openings CTH1 and CTH2 may vary. For example, the first contact opening CTH1 may have a greater planar area than the second contact opening CTH2. In an embodiment, the second contact opening CTH2 may have a greater planar area than the first contact opening CTH1 as shown, for example, in FIG. 3A.

The first contact opening CTH1 may be spaced apart from the support pillars SP. The first contact opening CTH1 might not contact the support pillars SP. The first contact opening CTH1 might not expose the support pillars SP. The support pillars SP may be disposed around the first contact opening CTH1 and spaced apart from each other. The first contact opening CTH1 may have a circular planar shape. For example, but not limited to, the first contact opening CTH1 may have a circular planar shape as shown in FIG. 3A.

The first spacer SPA1 may be formed on an inner side surface of the first contact opening CTH1. The first spacer SPA1 may have a cylindrical shape. The first spacer SPA1 might not contact the support pillars SP.

The first contact plug CP1 may fill an inside of the first spacer SPA1. The first contact plug CP1 may be surrounded by the first spacer SPA1. A side wall of the first contact plug CP1 might not be exposed by the first spacer SPA1. The first contact plug CP1 may have a cylindrical shape.

The second contact opening CTH2 may contact the support pillars SP. The second contact opening CTH2 may contact the dummy channel layer DCH of each of the support pillars SP. The second contact opening CTH2 may expose the dummy channel layers DCH. The second contact opening CTH2 may penetrate the dummy memory layer DML of each of the support pillars SP and may be in direct contact with the dummy channel layer DCH. The support pillars SP may be disposed along a side wall of the second contact opening CTH2. A planar shape of the second contact opening CTH2 may include concave portions that correspond to the dummy channel layers DCH, rather than a circular shape. For example, a portion of the side wall of the second contact opening CTH2, which contacts the dummy channel layers DCH, may have a concave shape that protrudes toward the inside or center of the second contact opening CTH2. Another portion of the side wall of the second contact opening CTH2, which does not contact the dummy channel layers DCH, may have a convex shape that protrudes toward the outside or away from the center of the second contact opening CTH2. In an embodiment, another portion of the side wall of the second contact opening CTH2, which does not contact the dummy memory layers DML, may have a convex shape that protrudes toward the outside or away from the center of the second contact opening CTH2.

The second spacer SPA2 may be formed on an inner side surface of the second contact opening CTH2. For example, the second spacer SPA2 may be formed conformally on the side wall of the second contact opening CTH2. The second spacer SPA2 may contact the support pillars SP. The second spacer SPA2 may have a cylindrical shape that has a concave portion and a convex portion. For example, the concave portion of the second spacer SPA2 may contact the dummy channel layers DCH of the support pillars SP. In addition, the convex portion of the second spacer SPA2 might not contact the support pillars SP.

The second contact plug CP2 may fill an inside of the second spacer SPA2. The second contact plug CP2 may be surrounded by the second spacer SPA2. A side wall of the second contact plug CP2 might not be exposed by the second spacer SPA2. The second contact plug CP2 may be spaced apart from the dummy channel layer DCH by the second spacer SPA2. In an embodiment, the second contact plug CP2 may be spaced apart from the dummy memory layer DML by the second spacer SPA2. The second contact plug CP2 may have a cylindrical shape that has a concave portion or concave portions.

Referring to FIG. 3B, the memory device 100 may include a stack structure STK. The stack structure STK may include conductive layers CD and interlayer insulating layers IIL. The conductive layers CD and the interlayer insulating layers IIL may be alternately stacked in the Z direction. The conductive layers CD may include at least one of but not limited to tungsten (W), cobalt (Co), nickel (Ni), molybdenum (Mo), silicon (Si), and polysilicon (poly-Si). The interlayer insulating layers IIL may include an oxide layer (e.g., a silicon oxide layer). The conductive layers CD may correspond to gate lines (e.g., the drain select lines DSL, the word lines WL, or the source select lines SSL in FIG. 1).

The cell plug CPL may penetrate the stack structure STK. The memory cells and the select transistors may be formed at intersections of the cell plug CPL and the conductive layers CD.

The support pillars SP may penetrate the stack structure STK. The support pillars SP may have the same height as the cell plug CPL. An upper surface of the stack structure STK, an upper surface of the cell plug CPL, and upper surfaces of the support pillars SP may be located at the same level. For example, the stack structure STK that is penetrated by the support pillars SP (e.g., the contact region CTR in FIG. 3A) might not include a stepped structure.

Each of the cell plugs CPL and the support pillars SP may include irregularities. For example, the stack structure STK may include an upper stack structure and a lower stack structure. Each of the cell plugs CPL and the support pillars SP may include the irregularities at an interface between the upper stack structure and the lower stack structure. The memory layer ML, the channel layer CH, and the gap fill layer GF may include a portion that protrudes toward the stack structure STK in a region adjacent to the interface between the upper stack structure and the lower stack structure. In addition, the dummy memory layer DML, the dummy channel layer DCH, and the dummy gap fill layer DGF may include a portion that protrudes toward the stack structure STK in the region adjacent to interface between the upper stack structure and the lower stack structure.

A width of the support pillar SP in the X direction may be greater than a width of the cell plug CPL in the X direction. For example, a volume of the support pillar SP may be greater than a volume of the cell plug CPL. Each thickness (e.g., a thickness of the channel layer CH and a thickness of the dummy channel layer DCH) of the configurations included in the cell plug CPL and the support pillar SP will be described below with reference to FIG. 3C.

The first contact opening CTH1 may extend toward a first conductive layer CD1 from the upper surface of the stack structure STK. The second contact opening CTH2 may extend toward a second conductive layer CD2 from the upper surface of the stack structure STK. The second conductive layer CD2 may be located lower than the first conductive layer CD1 (e.g., in an opposite direction to the Z direction). Accordingly, a depth of the second contact opening CTH2 may be greater than a depth of the first contact opening CTH1.

A width of the second contact opening CTH2 in the X direction may be greater than a width of the first contact opening CTH1 in the X direction. For example, when the second contact opening CTH2, which has a greater length in the Z direction than the first contact opening CTH1, is formed, the width of the second contact opening CTH2 in the X direction may increase compared to that of the first contact opening CTH1. Accordingly, the first contact opening CTH1 might not contact the support pillar SP and the second contact opening CTH2 may contact the support pillar SP.

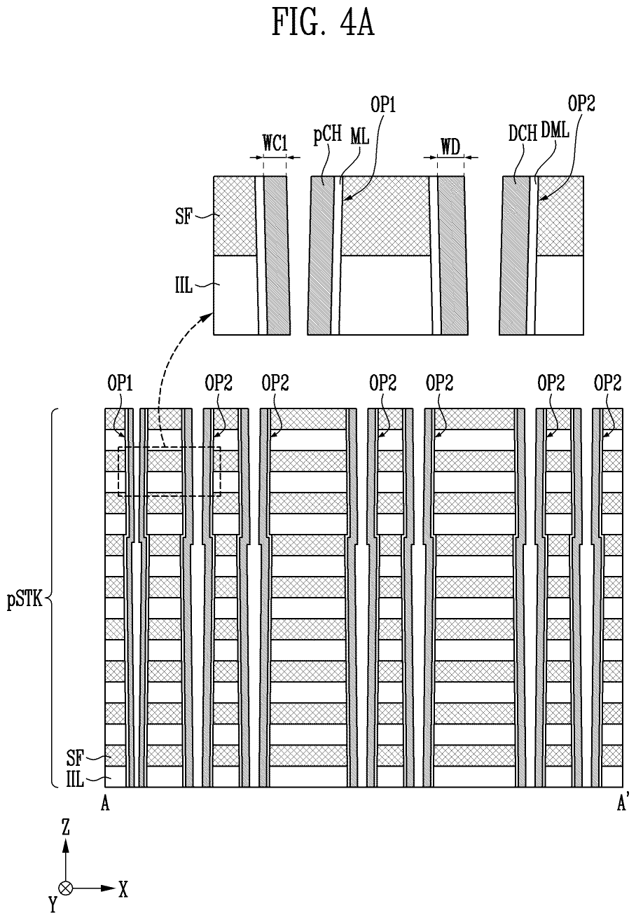

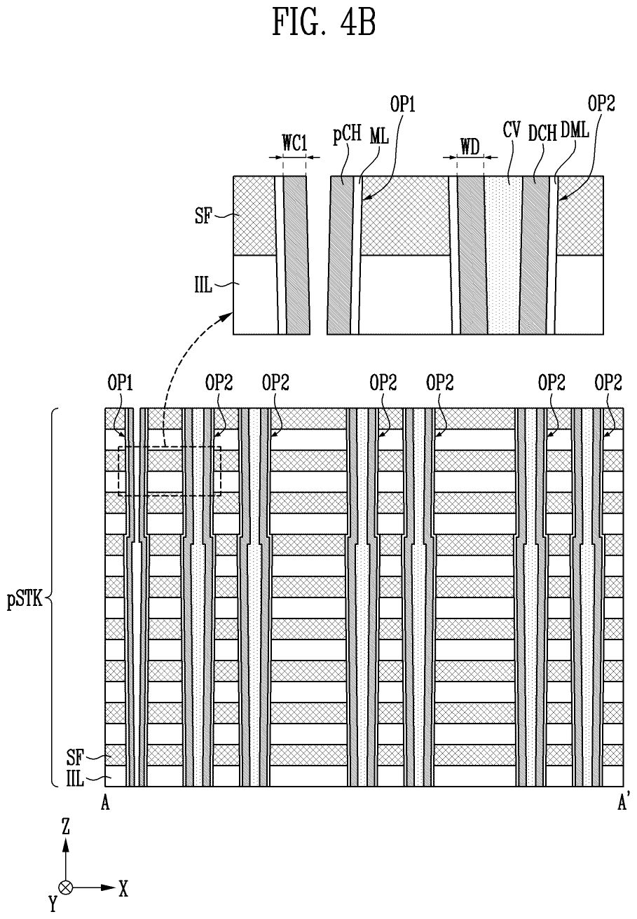

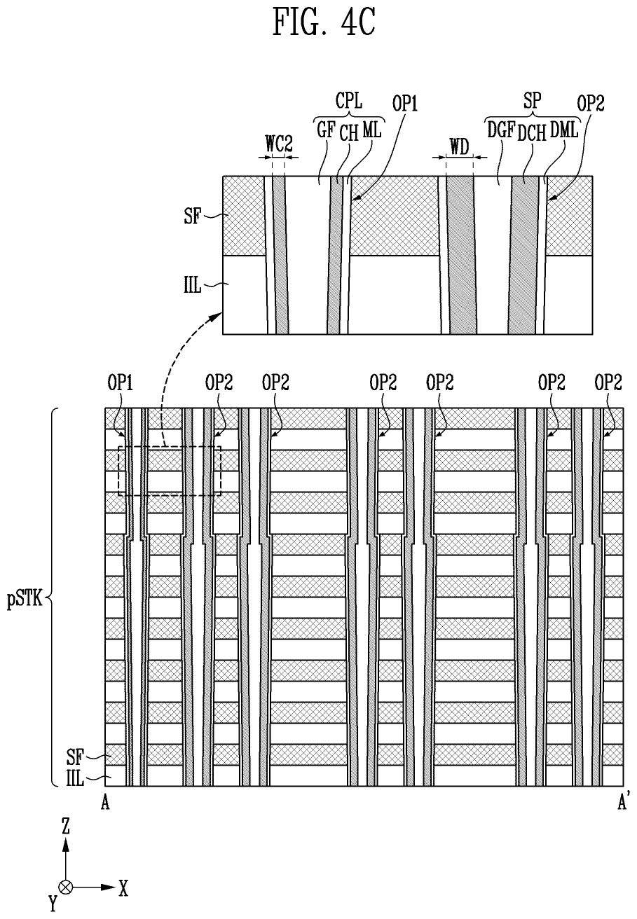

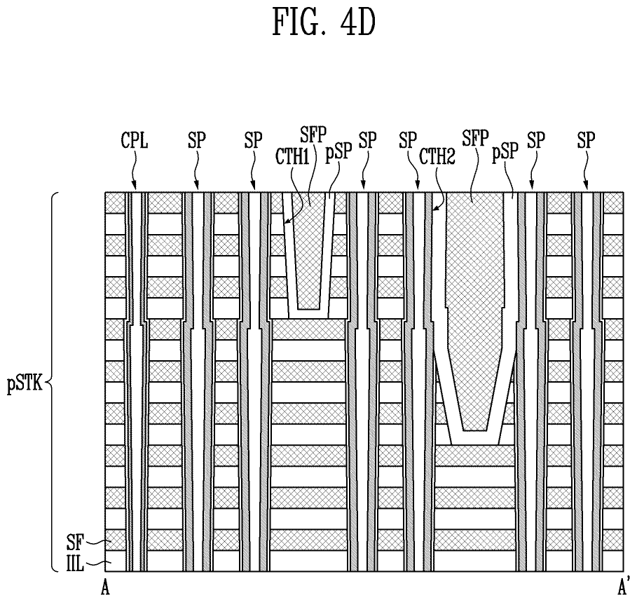

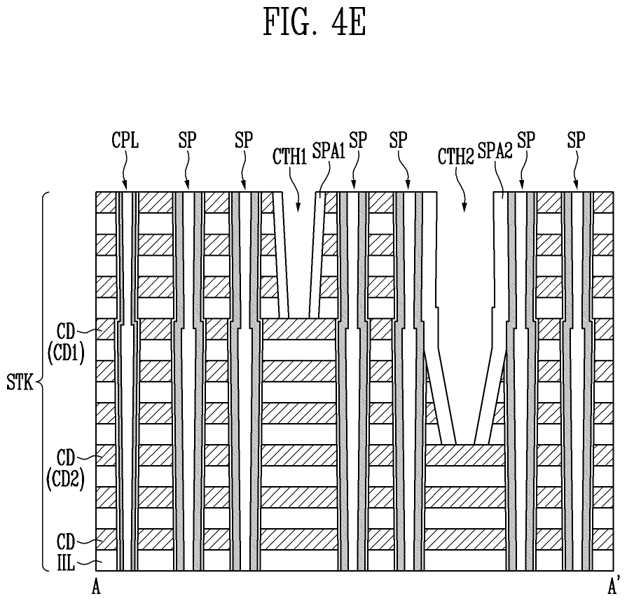

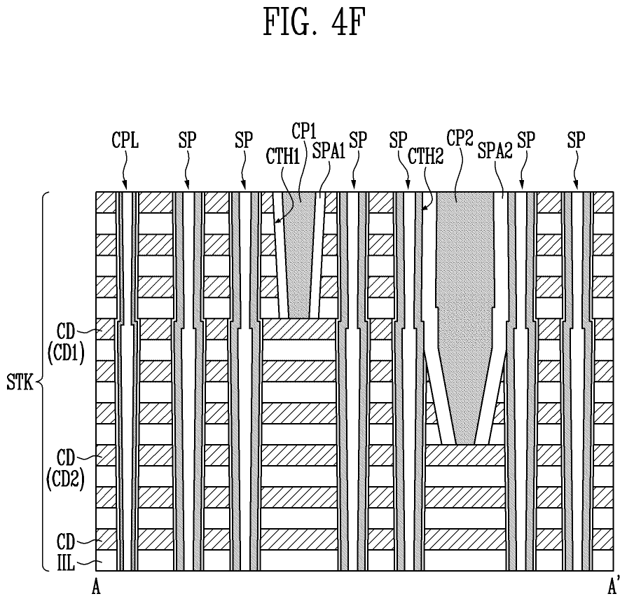

When the second contact opening CTH2 is formed, the dummy channel layer DCH included in the support pillar SP may serve as an etch stop layer. The dummy channel layer DCH may prevent or mitigate an excessive increase of the width of the second contact opening CTH2 in the X direction (or the width in the Y direction). The dummy channel layer DCH, which serves as the etch stop layer, will be described below in more detail with references to FIGS. 4A to 4F.

The first spacer SPA1 and the first contact plug CP1 may be disposed in the first contact opening CTH1. The first contact plug CP1 may contact the first conductive layer CD1. The first spacer SPA1 may be formed on the side surface of the first contact plug CP1. The first spacer SPA1 may separate the first contact plug CP1 from the conductive layers CD that are located above the first conductive layer CD1.

The second spacer SPA2 and the second contact plug CP2 may be disposed in the second contact opening CTH2. The second contact plug CP2 may contact the second conductive layer CD2. The second spacer SPA2 may be formed on a side surface of the second contact plug CP2. The second spacer SPA2 may separate the second contact plug CP2 from the conductive layers CD that are located above the second conductive layer CD2.

An outer surface of the second spacer SPA2 may contact the dummy channel layer DCH, the dummy memory layer DML, and the stack structure STK. A lower surface of the second spacer SPA2 may contact the second conductive layer CD2. An inner surface of the second spacer SPA2 may contact the second contact plug CP2.

Referring to FIG. 3C, a first thickness WD of the dummy channel layer DCH included in the support pillar SP may be greater than a thickness WC of the channel layer CH included in the cell plug CPL. In an embodiment, the more the first thickness WD of the dummy channel layer DCH, which serves as an etch stop layer, is increased, the more effectively an excessive increase in the size of the second contact opening CTH2 may be prevented or mitigated. In addition, in an embodiment, warpage of the stack structure STK may be reduced and damage to the stack structure STK caused by factors such as dishing may be reduced.

A thickness of the dummy memory layer DML included in the support pillar SP may be smaller than, equal to, or greater than a thickness of the memory layer ML included in the cell plug CPL. In addition, a width of the dummy gap fill layer DGF included in the support pillar SP in the X direction (or a width in the Y direction) may be smaller than, equal to, or greater than a width of the gap fill layer GF included in the cell plug CPL in the X direction (or a width in the Y direction).

According to an embodiment of the present disclosure, the structural stability of the stack structure STK may be enhanced by increasing the first thickness WD of the dummy channel layer DCH included in the support pillar SP to be greater than that of the thickness WC of the channel layer CH included in the cell plug CPL.

FIGS. 4A to 4F are diagrams illustrating a method of manufacturing a memory device including support pillars according to an embodiment of the present disclosure. FIGS. 4A to 4F each show a cross-section taken along line A-A′ of FIG. 3A.

Referring to FIG. 4A, a preliminary stack structure pSTK in which interlayer insulating layers IIL and sacrificial layers SF are alternately stacked may be formed. The interlayer insulating layers IIL may include an insulating material. For example, the interlayer insulating layers IIL may include an oxide layer (e.g., a silicon oxide layer). The sacrificial layers SF may include a material that may be selectively removed in a subsequent process. The sacrificial layers SF may include a material having an etch selectivity different from that of the interlayer insulating layers IIL. For example, the sacrificial layers SF may include a nitride layer.

Subsequently, a first opening OP1 and a second opening OP2 penetrating the preliminary stack structure pSTK may be formed. The first opening OP1 may penetrate a cell region (e.g., the cell region CR in FIG. 3A) of the preliminary stack structure pSTK. The second opening OP2 may penetrate a contact region (e.g., the contact region CTR in FIG. 3A) of the preliminary stack structure pSTK. A width of the second opening OP2 in the X direction may be greater than a width of the first opening OP1 in the X direction. A planar area of the second opening OP2 may be greater than a planar area of the first opening OP1. In an embodiment a width of the second opening OP2 in the Y direction may be greater than a width of the first opening OP1 in the Y direction. In an embodiment, a planar area of the first opening OP1 may be greater than a planar area of the second opening OP2.

Though not shown, the process of forming the first opening OP1 and the second opening OP2 may include a plurality of processes. For example, the plurality of processes may include forming a lower preliminary stack structure, forming lower openings penetrating the lower preliminary stack structure, forming a sacrificial material filling the lower openings, forming an upper preliminary stack structure over the lower preliminary stack structure, forming upper openings penetrating the upper preliminary stack structure, and removing the sacrificial material from the lower openings through the upper openings.

Subsequently, the memory layer ML may be formed on an inner side surface of the first opening OP1. In addition, the dummy memory layer DML may be formed on an inner side surface of the second opening OP2. The dummy memory layer DML and the memory layer ML may include the same material. The dummy memory layer DML and the memory layer ML may be formed simultaneously. For example, after a preliminary blocking layer, a preliminary trap charge layer, and a preliminary tunnel insulating layer are formed over the preliminary stack structure pSTK in which the first opening OP1 and the second opening OP2 are formed, a portion of the preliminary blocking layer, a portion of the preliminary trap charge layer, and a portion of the preliminary tunnel insulating layer that are located over the preliminary stack structure pSTK may be removed. Accordingly, a portion of the preliminary blocking layer, a portion of the preliminary trap charge layer, and a portion of the preliminary tunnel insulating layer that remain in the first opening OP1 may constitute the memory layer ML. In addition, a portion of the preliminary blocking layer, a portion of the preliminary trap charge layer, and a portion of the preliminary tunnel insulating layer that remain in the second opening OP2 may constitute the dummy memory layer DML. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Subsequently, a preliminary channel layer pCH may be formed in the first opening OP1. In addition, the dummy channel layer DCH may be formed in the second opening OP2. The preliminary channel layer pCH may be formed on an inner side surface of the memory layer ML and the dummy channel layer DCH may be formed on an inner side surface of the dummy memory layer DML. The dummy channel layer DCH may include the same material (e.g., silicon) as the preliminary channel layer pCH. The dummy channel layer DCH may be formed simultaneously with the preliminary channel layer pCH. For example, polysilicon may be formed over the preliminary stack structure pSTK in which the first opening OP1 and the second opening OP2 are formed, and then a portion of the polysilicon formed over the preliminary stack structure pSTK may be removed. Accordingly, a portion of the polysilicon remaining in the first opening OP1 may form the preliminary channel layer pCH and a portion of the polysilicon remaining in the second opening OP2 may form the dummy channel layer DCH.

A second thickness WC1 of the preliminary channel layer pCH may be greater than or equal to the first thickness WD of the dummy channel layer DCH. For example, polysilicon may be deposited on the preliminary stack structure pSTK so that the dummy channel layer DCH may have enough thickness (e.g., the first thickness WD) to serve as an etch stop layer in a subsequent process. When the dummy channel layer having the first thickness WD is formed in the second opening OP2, the preliminary channel layer pCH having the second thickness WC1, which is greater than or equal to the first thickness WD, may be formed.

Referring to FIG. 4B, a cover layer CV may fill an inside of the second opening OP2. The cover layer CV may fill an inside of the dummy channel layer DCH. The cover layer CV may cover the dummy channel layer DCH. The cover layer CV may prevent or mitigate the dummy channel layer DCH from being exposed. Though not shown, the cover layer CV may be formed over the preliminary stack structure pSTK. For example, the cover layer CV may cover an upper surface of a contact region (e.g., the contact region CTR in FIG. 3A) of the preliminary stack structure pSTK.

The preliminary channel layer pCH might not be covered by the cover layer CV. Since the cover layer CV does not cover a cell region (e.g., the cell region CR in FIG. 3A) of the preliminary stack structure pSTK, the preliminary channel layer pCH may be exposed to the outside.

Referring to FIG. 4C, a portion of the preliminary channel layer pCH may be removed to form the channel layer CH. The channel layer CH may have a third thickness WC2 that is smaller than the second thickness WC1 of the preliminary channel layer pCH. For example, the preliminary channel layer pCH may be etched to a predetermined thickness from an inner surface thereof to form the channel layer CH having the third thickness WC2 that is smaller than the second thickness WC1. The third thickness WC2 of the channel layer CH may be smaller than the first thickness WD of the dummy channel layer DCH.

When the channel layer CH is formed according to an embodiment of the present disclosure, the performance of the channel layer CH may be improved. For example, the grain size of the polysilicon included in the channel layer CH may be greater in the case where the preliminary channel layer pCH is deposited to the second thickness WC1 and then a portion of the preliminary channel layer pCH is etched so that the channel layer CH may remain with the third thickness WC2, compared to the case where the channel layer CH is deposited to the third thickness WC2.

Subsequently, the cover layer CV may be removed. After the portion of the preliminary channel layer pCH is etched to form the channel layer CH which is thinner than dummy channel layer DCH, the cover layer CV covering the preliminary channel layer pCH may be removed. As the cover layer CV is removed, the dummy channel layer DCH may be exposed to the outside.

Subsequently, the gap fill layer GF may be formed in the first opening OP1 and the dummy gap fill layer DGF may be formed in the second opening OP2. The gap fill layer GF may be surrounded by the channel layer CH. The memory layer ML, the channel layer CH, and the gap fill layer GF may constitute the cell plug CPL. The dummy memory layer DML, the dummy channel layer DCH, and the dummy gap fill layer DGF may form the support pillar SP.

Referring to FIG. 4D, the first and second contact openings CTH1 and CTH2 may be formed in the preliminary stack structure pSTK. The first and second contact openings CTH1 and CTH2 may penetrate at least one of the sacrificial layers SF and at least one of the interlayer insulating layers IIL. The first and second contact openings CTH1 and CTH2 may have different depths. For example, a depth of the second contact opening CTH2 may be greater than a depth of the first contact opening CTH1. The first and second contact openings CTH1 and CTH2 may have different planar areas. For example, the width of the second contact opening CTH2 in the X direction may be greater than the width of the first contact opening CTH1 in the X direction.

The first contact opening CTH1 may be spaced apart from the support pillar SP. The first contact opening CTH1 may expose side surfaces of the sacrificial layers SF and the interlayer insulating layers IIL. The first contact opening CTH1 might not expose the support pillar SP. The width of the first contact opening CTH1 in the X direction may decrease from top to bottom.

The second contact opening CTH2 may contact the support pillar SP. The second contact opening CTH2 may expose side surfaces of the sacrificial layers SF and the interlayer insulating layers IIL. In addition, the second contact opening CTH2 may expose the dummy channel layer DCH. For example, when the second contact opening CTH2 is formed, a portion of the dummy memory layer DML may be etched to expose the dummy channel layer DCH. Accordingly, the second contact opening CTH2 may contact the dummy channel layer DCH. The width of the second contact opening CTH2 in the X direction may decrease from top to bottom. Accordingly, an upper portion of the second contact opening CTH2 may contact the dummy channel layer DCH and a lower portion of the second contact opening CTH2 may contact the preliminary stack structure pSTK. A portion of the second contact opening CTH2 may overlap a portion of the support pillar SP.

When the second contact opening CTH2 is formed, the dummy channel layer DCH may serve as an etch stop layer. Accordingly, in an embodiment, the dummy channel layer DCH may prevent or mitigate a planar area of the second contact opening CTH2 from being widened excessively. Accordingly, the planar area of the second contact opening CTH2 may have a shape with the concave portions rather than a circular shape, as shown in FIG. 3A.

Spacer layers pSP may be formed in the first and second contact openings CTH1 and CTH2. The spacer layers pSP may extend along side surfaces and lower surfaces of the first and second contact openings CTH1 and CTH2. The spacer layer pSP may cover the preliminary stack structure pSTK so that the preliminary stack structure pSTK might not be exposed through the second contact opening CTH2. In addition, the spacer layer pSP may cover the dummy channel layer DCH and the dummy memory layer DML so that both of the dummy channel layer DCH and the dummy memory layer DML might not be exposed through the second contact opening CTH2. The spacer layer pSP may include an insulating layer (e.g., an oxide layer).

Sacrificial plugs SFP may be formed in the first and second contact openings CTH1 and CTH2. The sacrificial plugs SFP may fill insides of the spacer layers pSP. The sacrificial plugs SFP may be surrounded by the spacer layers pSP. The sacrificial layers SF may include a nitride layer.

Referring to FIG. 4E, the sacrificial layers SF may be replaced with the conductive layers CD. For example, the sacrificial layers SF included in the preliminary stack structure pSTK may be removed and the conductive layers CD may be formed in areas where the sacrificial layers SF are removed. The stack structure STK may include the conductive layers CD and the interlayer insulating layers IIL.

Subsequently, the sacrificial plugs SFP may be removed in the first and second contact openings CTH1 and CTH2. An isotropic etching process may be performed to selectively etch the sacrificial plugs SFP.

Subsequently, a lower surface of the spacer layer pSP may be removed. An anisotropic dry etching process may be performed to selectively etch the lower surface of the spacer layer pSP. The spacer layer pSP remaining in the first contact opening CTH1 may be referred to as the first spacer SPA1 and the spacer layer pSP remaining in the second contact opening CTH2 may be referred to as the second spacer SPA2.

As the lower surface of the spacer layer pSP is removed, an upper surface of each of the conductive layers CD may be exposed. For example, an upper surface of the first conductive layer CD1 may be exposed through the first contact opening CTH1. In addition, an upper surface of the second conductive layer CD2 may be exposed through the second contact opening CTH2.

Referring to FIG. 4F, the first and second contact plugs CP1 and CP2 may be formed in the first and second contact openings CTH1 and CTH2. The first and second contact plugs CP1 and CP2 may be formed by filling the first and second spacers SPA1 and SPA2 with a conductive material. For example, the first contact plug CP1 contacting the first spacer SPA1 may be formed in the first contact opening CTH1. In addition, the second contact plug CP2 contacting the second spacer SPA2 may be formed in the second contact opening CTH2.

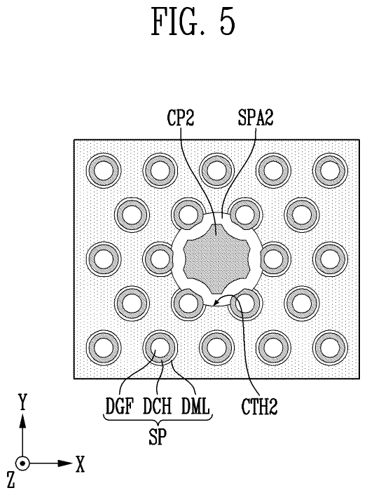

FIG. 5 is a diagram illustrating a memory device including support pillars according to another embodiment of the present disclosure. In FIG. 5, the configurations overlapping with those shown in FIGS. 3A to 3C will be omitted or simplified.

Referring to FIG. 5, a portion of an outer side surface of the dummy channel layer DCH included in the support pillar SP may have a concave shape. A portion of the concave portions of the second contact opening CTH2 may have a convex shape. For example, a portion of the dummy channel layer DCH may be etched when the second contact opening CTH2 is formed. Accordingly, the side surface of the second contact opening CTH2 may include irregularities.

It will be understood that the above descriptions are made to explain the configurations shown FIGS. 3A to 5, and the present disclosure is not limited to those shown in FIGS. 3A to 5. That is, as long as the thickness of the dummy channel layer DCH (e.g., an average thickness and a maximum thickness) is greater than the thickness of the channel layer CH, the specific shape of the dummy channel layer DCH is not limited to those shown in FIGS. 3A to 5. For example, some of the dummy channel layers DCH contacting the second contact opening CTH2 might not be etched, and other dummy channel layers DCH may be etched.

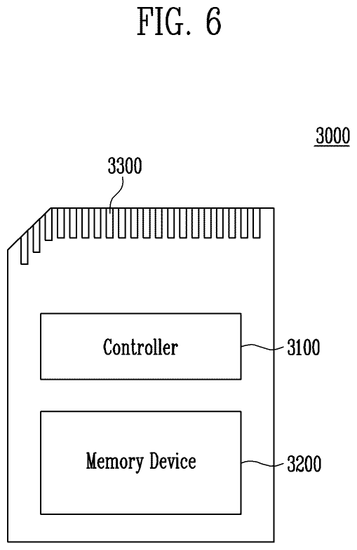

FIG. 6 is a diagram illustrating a memory card system 3000 to which a memory device according to an embodiment of the present disclosure is applied.

Referring to FIG. 6, the memory card system 3000 may include a controller 3100, a memory device 3200, and a connector 3300.

The controller 3100 may be coupled to the memory device 3200. The controller 3100 may be configured to access the memory device 3200. For example, the controller 3100 may control a program operation, a read operation or an erase operation, or a background operation of the memory device 3200. The controller 3100 may be configured to provide an interface between the memory device 3200 and a host. The controller 3100 may be configured to drive firmware for controlling the memory device 3200. For example, the controller 3100 may include components such as but not limited to a Random Access Memory (RAM), a processing unit, a host interface, a memory interface, and an error corrector.

The controller 3100 may communicate with an external device through the connector 3300. The controller 3100 may communicate with the external device (e.g., the host) according to a specific communication protocol. For example, the controller 3100 may be configured to communicate with the external device through at least one of various communication protocols such as but not limited to a Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), Wi-Fi, Bluetooth, and NVMe protocols. For example, the connector 3300 may be defined by at least one of the above-described various communication protocols.

The memory device 3200 may include a plurality of memory cells and may be configured in the same manner as the memory device 100 shown in FIG. 1.

The controller 3100 and the memory device 3200 may be integrated into a single semiconductor device to constitute a memory card. For example, the controller 3100 and the memory device 3200 may constitute a memory card such as but not limited to a personal computer (PC) card (Personal Computer Memory Card International Association (PCMCIA)), a Compact Flash (CF) card, a Smart Media Card (SM and SMC), a memory stick, a Multi-Media Card (MMC, RS-MMC, MMCmicro, or eMMC), an SD card (SD, miniSD, microSD, or SDHC), and a Universal Flash Storage (UFS).

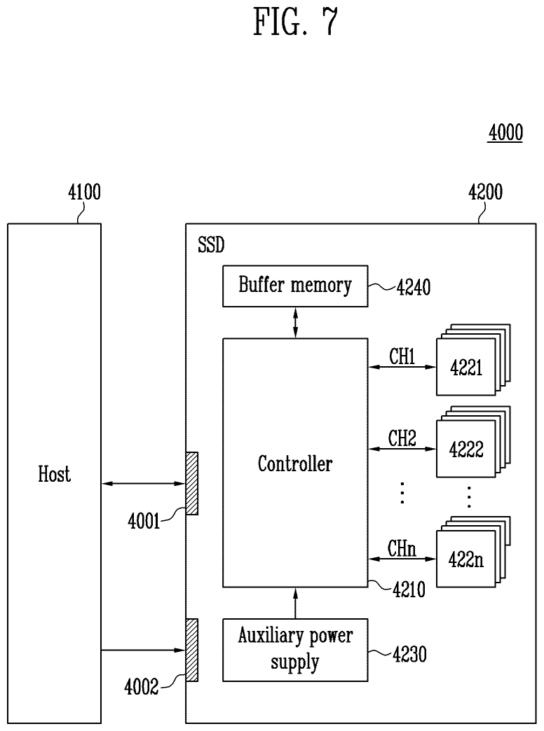

FIG. 7 is a diagram illustrating a solid state drive (SSD) system 4000 to which a memory device according to an embodiment of the present disclosure is applied.

Referring to FIG. 7, an SSD system 4000 may include a host 4100 and an SSD 4200. The SSD 4200 may exchange a signal with the host 4100 through a signal connector 4001, and may receive power through a power connector 4002. The SSD 4200 may include a controller 4210, a plurality of memory devices 4221 to 422n, an auxiliary power supply 4230, and a buffer memory 4240.

The controller 4210 may control the plurality of memory devices 4221 to 422n in response to a signal received from the host 4100. For example, the signal may be a signal based on an interface between the host 4100 and the SSD 4200. For example, the signal may be defined by at least one of interfaces such as but not limited to Universal Serial Bus (USB), Multi-Media Card (MMC), embedded MMC (eMMC), Peripheral Component Interconnection (PCI), PCI express (PCI-E), Advanced Technology Attachment (ATA), Serial-ATA (SATA), Parallel-ATA (PATA), Small Computer System Interface (SCSI), Enhanced Small Disk Interface (ESDI), an Integrated Drive Electronics (IDE), Firewire, Universal Flash Storage (UFS), WI-FI, Bluetooth, and NVMe interfaces.

The plurality of memory devices 4221 to 422n may include a plurality of memory cells configured to store data. Each of the plurality of memory devices 4221 to 422n may be configured in the same manner as the memory device 100 shown in FIG. 1. The plurality of memory devices 4221 to 422n may communicate with the controller 4210 through channels CH1 to CHn.

The auxiliary power supply 4230 may be coupled to the host 4100 through a power connector 4002. The auxiliary power supply 4230 may receive power input from the host 4100 and charge the power. When the supply of power from the host 4100 is not smooth, the auxiliary power supply 4230 may provide power of the SSD 4200. For example, the auxiliary power supply 4230 may be located inside or outside the SSD 4200. For example, the auxiliary power supply 4230 may be located on a main board and provide auxiliary power to the SSD 4200.

The buffer memory 4240 may serve as a buffer memory of the SSD 4200. For example, the buffer memory 4240 may store data received from the host 4100 or data received from the plurality of memory devices 4221 to 422n, or may store metadata (e.g., mapping tables) of the memory devices 4221 to 422n. The buffer memory 4240 may include volatile memories such as but not limited to DRAM, SDRAM, DDR SDRAM, and LPDDR SDRAM, or non-volatile memories such as FRAM, ReRAM, STT-MRAM, and PRAM.

According to various embodiments of the present disclosure, the structural stability of a stack structure may be enhanced by improving a structure of a support pillar.

What is claimed is:

1. A memory device, comprising:
a stack structure including a cell region and a contact region;
a cell plug located in the cell region and including a channel layer;
a support pillar located in the contact region and including a dummy channel layer; and
a contact opening contacting the support pillar,
wherein a thickness of the dummy channel layer is greater than a thickness of the channel layer.

2. The memory device of claim 1, wherein the contact opening is in contact with the dummy channel layer of the support pillar.

3. The memory device of claim 1, wherein the cell plug further comprises:
a memory layer surrounding the channel layer; and
a gap fill layer in the channel layer.

4. The memory device of claim 1, wherein the support pillar further comprises:
a dummy memory layer surrounding the dummy channel layer; and
a dummy gap fill layer in the dummy channel layer.

5. The memory device of claim 4, wherein the contact opening penetrates the dummy memory layer and is in direct contact with the dummy channel layer.

6. The memory device of claim 1, wherein the support pillar is substantially the same height as the cell plug.

7. The memory device of claim 1, wherein the channel layer and the dummy channel layer include substantially the same material.

8. The memory device of claim 1, wherein the stack structure includes a plurality of conductive layers spaced apart from each other in a vertical direction.

9. The memory device of claim 8, wherein the contact opening extends from an upper surface of the stack structure toward a first conductive layer among the plurality of conductive layers.

10. The memory device of claim 9, further comprising a contact plug in the contact opening,
wherein the contact plug is in contact with the first conductive layer.

11. The memory device of claim 9, further comprising a spacer extending along an inner side surface of the contact opening.

12. The memory device of claim 11, further comprising a contact plug in the contact opening,
wherein the spacer separates conductive layers disposed over the first conductive layer among the plurality of conductive layers and the contact plug from each other.

13. The memory device of claim 11, further comprising a contact plug in the contact opening,
wherein the spacer spaces apart the dummy channel layer from the contact plug.
